(19) United States
(12) Patent Application Publication
(10) Pub. No.: US 2009/0267157 A1
(43) Pub. Date: Oct. 29, 2009

(54) METHOD OR MANUFACTURING A SEMICONDUCTOR DEVICE AND SEMICONDUCTOR DEVICE OBTAINED BY USING SUCH A METHOD

(75) Inventors: Marcus Johannes Henricus Van Dal, Heverlee (BE); Jacob C. Hooker, Kessel-Lo (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/721,039

(22) PCT Filed: Dec. 5, 2005
(86) PCT No.: PCT/IB05/54046

§ 371 Date: Mar. 19, 2009

(30) Foreign Application Priority Data
Dec. 6, 2004 (EP) 04106304.1

(51) Int. Cl. H01L 27/092; H01L 21/28

(52) U.S. Cl. 257/369; 438/216; 257/E27.062; 257/E21.19; 257/E21.192

(57) ABSTRACT

The invention relates to a method of manufacturing a semiconductor device (10) comprising a semiconductor body (2) provided with a field effect transistor (3), wherein a polycrystalline silicon region (5) with a metal layer (6) deposited thereon is transformed into a metal suicide gate electrode (3D) so as to form the gate electrode (3D), whereupon the part of the metal layer (6) that remains after this reaction is removed by etching. According to the invention, the semiconductor body (2) is exposed in a thermal treatment to an atmosphere comprising an oxygen-containing compound before or during the formation of the metal suicide (3D) gate electrode. In this way a transistor (3) comprising a gate electrode (3D) having a low resistance is obtained. The invention is particularly suitable for the manufacture of a PMOST, with Platinum or Palladium being used as the metal layer.

The invention relates to a method of manufacturing a semiconductor device consisting of a substrate and a semiconductor body comprising a field effect transistor having a source and drain region and a channel region of a first conductivity type located therebetween and a gate electrode separated from the channel region by a dielectric layer, which gate electrode comprises a conductor, wherein a polycrystalline silicon layer is deposited on the semiconductor body provided with said dielectric layer so as to form the gate electrode, which polycrystalline silicon layer is subsequently removed again outside the channel region, and wherein a metal layer is deposited on the semiconductor body on top of the remaining portion of the polycrystalline silicon layer above the channel region, after which the remaining portion of the polycrystalline silicon layer is reacted with the metal layer by means of a thermal treatment, forming a metal silicide that forms the conductor for the gate electrode, after which the portion of the metal layer that remains after the reaction is removed by etching. Such a method, in which the gate electrode is formed of a metal silicide conductor, is very attractive for future (C)MOSFET (=Complimentary Metal Oxide Semiconductor Field Effect Transistor) silicon devices, wherein the series resistance is reduced, the ingress of boron atoms into the gate oxide is opposed and the occurrence of depletion layer effects in a gate electrode that would consist of polycrystalline silicon is prevented. It is noted that the dielectric layer may comprise not only an oxide or a silicon oxynitride, but also a material such as silicon nitride or even a dielectric material that does not contain silicon.

A method of the kind referred to in the introduction is known from U.S. Pat. No. 6,620,718, which was published on Sep. 16, 2003.

Said patent discloses a method of manufacturing a MOS transistor wherein a metal layer is deposited on a polysilicon gate electrode region present on a dielectric layer. The polysilicon is reacted with the portion of the metal layer on top of the polysilicon in a thermal treatment, resulting in the formation of a metal silicide. Following that, the remaining portions of the metal layer, which may be present on the metal silicide, but which are in any case present on either side of the gate electrode, are removed by etching. According to the aforesaid patent, the source and drain regions are first provided with a further metal silicide in a similar manner. On said further metal silicide, a layer containing an oxide is selectively formed on the metal silicide of the source and drain regions so as to form the metal silicide of the gate electrode. This makes it possible to deposit different types of metal silicides and/or metal silicides of varying thickness on the metal silicides of the source and drain regions on the one hand and the gate electrode on the other hand, because the layer containing an oxide protects the metal silicide of the source and drain regions from reacting with a metal layer to be deposited at a later stage.

The selective coating of the metal silicide of the source and drain regions is realized by exposing it to an oxygen-containing atmosphere after being thermally grown. In this way an oxygen-containing layer is deposited on the metal silicides thus formed.

A drawback of the known method is that in some cases the gate electrode formed by means of said method does not have the desired properties. Thus, in particular the resistance of the gate electrode of a PMOST obtained by using said method is too high if the gate electrode is formed of platinum of palladium silicide. This is very disadvantageous because these metal silicides, which have a work function of about 5.2 eV, are in principle quite suitable for use as the material for a gate electrode of a PMOS transistor. Such transistors are essential, in a CMOS IC in any case.

The object of the present invention is, therefore, to provide a method by means of which a transistor is obtained whose gate electrode has the desired properties and by means of which in particular a P-MOS transistor whose gate electrode contains platinum or palladium silicide can be manufactured and which does not have the aforesaid drawback.

In order to achieve that object, a method of the kind referred to in the introduction is according to the invention characterized in that the semiconductor body is exposed in a thermal treatment to an atmosphere that comprises an oxygen-containing compound during or after the formation of the metal silicide. The invention is in the first place based on the perception that even if the metal silicide of the gate electrode is exclusively exposed to an inert atmosphere, the resistance thereof will be too high, in particular when the silicide is a silicide of platinum or palladium. The invention is furthermore based on the perception that a very aggressive etchant, such as a mixture of concentrated hydrochloric acid and concentrated nitric acid, is required for removing the remaining portions of a platinum or palladium layer, and that consequently a substantial portion of the gate electrode is converted into an oxide. The invention is furthermore based on the perception that a suitable protection of the gate electrode oxide against aggressive etchants, such as the aforesaid mixtures of concentrated hydrochloric acid and concentrated nitric acid, is obtained by selectively forming a very thin oxide layer on the surface of the metal silicide of the gate electrode in a controlled manner. Said thin oxide layer can readily be removed after the removal of the remaining portions of the metal layer, for example by dipping in an aqueous solution of hydrogen fluoride. It is also possible not to remove the oxide layer, if desired, and use it for insulating the—upper side of the—gate electrode.

Surprisingly, exposing a formed metal silicide to an oxygen-containing atmosphere while heating, as is done in the known method, appears to have significant advantages also for the metal silicide of the gate electrode. In addition, the gate electrode can thus be selectively provided with the desired protection in a very simple manner.

In a preferred embodiment, the metal silicide of the gate electrode is exposed during the formation thereof to an atmosphere comprising an oxygen-containing compound. It has become apparent that a thin oxide layer readily forms on the surface of the metal silicide in particular at the start of the silicide deposition process, when the metal/silicon ratio of the silicide formed up to that point is (much) greater than in the final metal silicide.

In an attractive modification, the formation of the metal silicide and the exposure to the atmosphere comprising an oxygen-containing compound are carried out in a single thermal treatment step. The method is very simple in that case.

As already noted and explained above, platinum or palladium is preferably selected as the material for the metal layer. The remaining portions thereof can readily be removed by means of a—preferably water-diluted—mixture of concentrated hydrochloric acid and concentrated nitric acid.

Advantageously, a (rapid) thermal tempering step is used for the thermal treatment, using a temperature of 400-700 degrees Celsius and a period of 30 seconds to 20 minutes, preferably a temperature of 600-700 degrees Celsius and a period of 30 seconds to 1 minute. Preferably oxygen is used as the oxygen-containing compound. The atmosphere may furthermore contain one or more inert gases, such as nitrogen or argon. An oxygen treatment that has appeared to be suitable comprises a gas flow of pure oxygen, for example. Also air may be used. Of course other conditions may appear to be optimal for other oxygen-containing compounds, such as a nitrogen oxide or water vapour.

As already noted before, the aforesaid metal silicides with a base of platinum of palladium are very suitable for a PMOS transistor. Preferably the n-conductivity type is selected for the first conductivity type, therefore. In use, the p-type channel of the PMOST is formed in the channel region in that case.

Preferably, also NMOS transistors are formed in one process, as a result of which the so-termed CMOS IC's can be obtained. In that case it is preferable to select a silicide of Hafnium or Ytterbium as the material for the gate electrode of the NMOS transistor. These materials have a work function of about 4.2 eV, which is a suitable value for an NMOS transistor.

Finally, the invention relates to a semiconductor device obtained by using a method according to the invention.

The invention will now be explained in more detail with reference to an embodiment and the drawing, in which

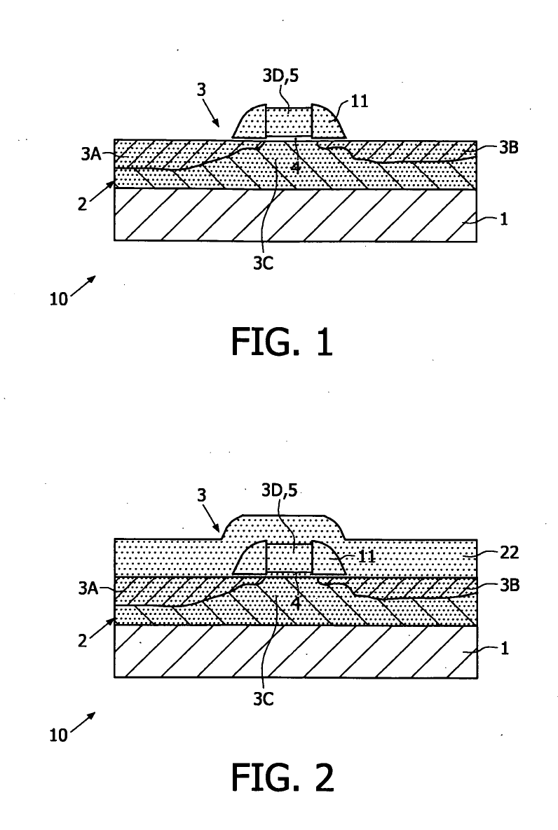

FIGS. 1-7 are schematic, cross-sectional views of a semiconductor device, seen in a direction perpendicular to the thickness direction, showing successive stages of the manufacture thereof by means of an embodiment of a method according to the invention.

The figures are not drawn to scale, and some dimensions, such as the dimensions in the thickness direction, are exaggerated for the sake of clarity. Corresponding areas or parts are as much as possible indicated by the same numerals in the various figures.

FIGS. 1-7 schematically show a semiconductor device in cross-sectional view, in a direction perpendicular to the thickness direction, during successive stages of the manufacture by means of an embodiment of a method according to the invention. The starting point in the formation of the device 10 (see FIG. 1) of a semiconductor body 2 comprising a substrate 1, in this case consisting of p-type silicon, in which a MOSFET 3 will be formed at the location of an n-type semiconductor region 3C formed in the p-type (in this case) substrate 1, which forms the channel region 3A of the transistor 3, in this case a PMOS transistor. If desired, one (or more) NMOS transistors can be formed in an adjacent part of the semiconductor body. Electrically insulating regions of, for example, silicon dioxide, are present on either side of the channel region 3C (not shown) inter alia in that case. The surface of the semiconductor a body 2 is coated with a dielectric layer 4, which contains silicon dioxide (in this case) and which has a thickness of 0.5-1.5 nm. On said layer a polycrystalline silicon 5 is deposited in a thickness of, for example, 20-100 nm.

Then the polysilicon layer 5 is patterned by photolithography and etching. Using the patterned polysilicon region 5 as a mask, thin and low doped extensions of the source and drain regions 3A, 3B of the transistor 3 to be formed are formed in the semiconductor body 2, for example by means of ion implantation. After the provision of spacers 11 made of silicon oxide or silicon nitride, higher doped and thicker portions of the source and drain regions 3A, 3B are formed, in this case by means of ion implantation again.

Then metal silicides may be formed on the surface of the semiconductor body 2 at the location of the source and drain regions 3A, 3B. These are not shown in the figure. The upper side of the gate electrode contains a thin protective layer (not shown in the drawing) in that case, which is deposited immediately after the deposition of the poly Si and which is patterned simultaneously therewith.

Following this (see FIG. 2), an insulating layer 22, for example of silicon dioxide, is deposited by means of a CVD (=Chemical Vapour Deposition) process. This layer functions to protect the metal silicides regions that have been formed at the location of the source and drain regions 3A, 3B. If desired, it is also possible to realize said protection in the same manner as with the known method, viz. by means of a thermal treatment in an oxygen-containing atmosphere, as a result of which the metal silicides of the source and drain regions are selectively coated with a thin oxide skin. The method that is described in this example has the advantage that it is also possible to use metals for the metal silicides of the source and drain regions 3A, 3B that cannot be used in the known method for selective coating with a thin insulating layer.

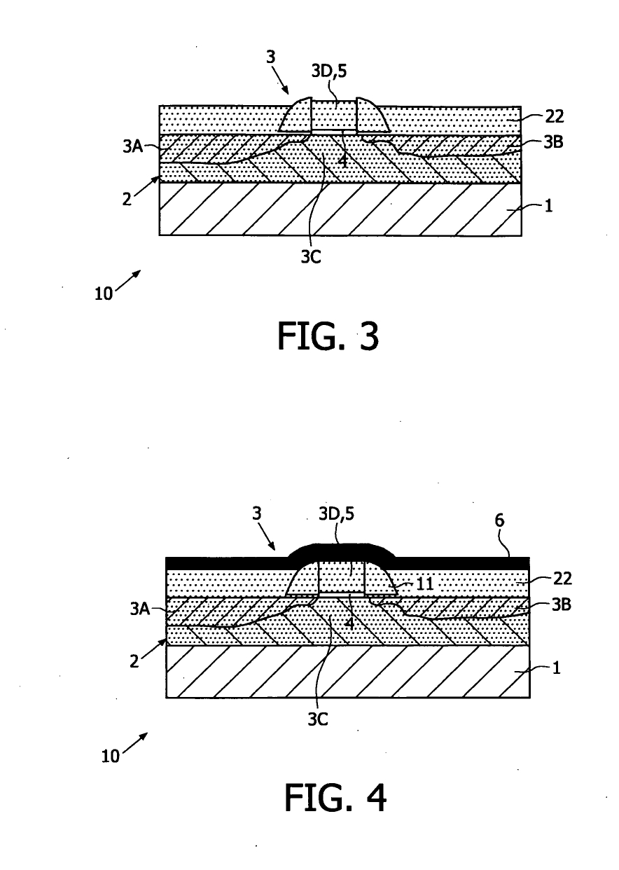

Then (see FIG. 3) the semiconductor body 2 is flattened by means of a CMP (=Chemical Mechanical Polishing) operation, whereby the poly Si region 5 is exposed. A protective layer that may be present on that region 5 is also removed thereby, so that a separate removing step is not required.

Then (see FIG. 4) a metal layer 6, in this case made of platinum and having a thickness of 10-120 nm, is applied by means of a PVD (=Physical Vapour Deposition) technique, such as vacuum metallizing or sputtering.

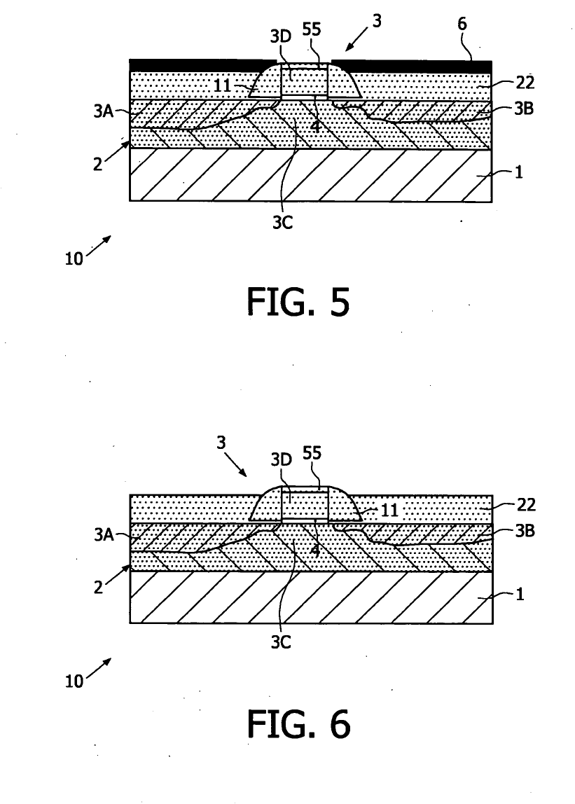

Subsequently (see FIG. 5) the semiconductor body 2 is subjected to a thermal treatment in an oxygen-containing atmosphere. A suitable atmosphere contains nitrogen, for example, to which 20 vol. % oxygen has been added. The thermal treatment is preferably, as in this example, an RPA (=Rapid Thermal Anneal) treatment. A suitable treatment is, for example, a treatment at 600 degrees Celsius for a period of 30 seconds. On the one hand the poly Si region 5 is converted into a platinum silicide such as PtSi or Pt₂Si by reacting with the platinum layer 6 during said treatment, and on the other hand—due to the presence of oxygen—a thin (silicon) oxide layer 55 is formed on the metal silicide gate electrode 3D.

Following that (see FIG. 6), the remaining portions of the platinum layer 6 are removed by etching. Said portions are in any case present on either side of the gate electrode 3D on the semiconductor body 2, but they may also comprise a portion of the platinum layer 6 which did not react with the poly Si region 5 and which is present on the platinum silicide gate electrode 3D. Preferably a mixture of concentrated hydrochloric acid and concentrated nitric acid—whether or not diluted—is used for etching the platinum layer 6. Thus, diluted acqua regia, among other substances, which contains concentrated hydrochloric acid and concentrated nitric acid in a volume ratio of 3:1, has appeared to be suitable for this purpose. An etchant that has appeared to be very suitable comprises a mixture containing 460 ml of hydrochloric acid, 60 ml of nitric acid and 800 ml of water. Etching will take place at 85° Celsius in that case.

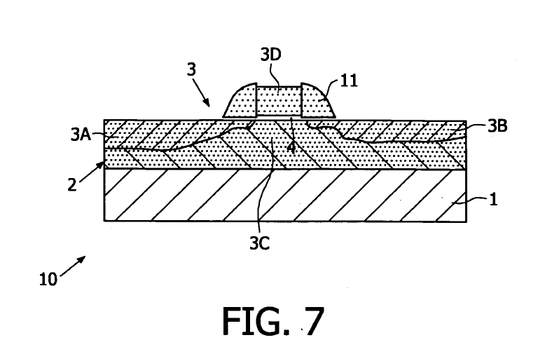

Subsequently (see FIG. 7) the insulating coatings 22,55 are removed again by etching, for example in an aqueous solution of hydrogen fluoride. The spacers 11 are preferably made of silicon nitride in that case, which is spared during such an etching process.

Following this, manufacture is continued, as usual in a (C)MOS technology. Thus the semiconductor a body 2 is coated with further insulating layers and provided with connection regions and possibly with connection conductors. Individual devices 10 are obtained by means of a separate technique, such as sawing.

The invention is not limited to the embodiment as described above, as many variations and modifications are possible for those skilled in the art within the scope of the invention. Thus it is possible to manufacture devices having a different geometry and/or different dimensions. Instead of using a substrate of Si it is also possible to use a substrate of glass, ceramics or a plastic material. The semiconductor body can be made up of the so-termed SOI (=Silicon on Insulator) in that case. Use may or may not be made of a so-termed substrate transfer technique for this purpose.

It is furthermore noted that it is possible within the framework of the invention to use different materials, for example different metals, than the materials used in the examples. It is also possible to use different deposition techniques for the aforesaid materials or other materials, such as epitaxy, CVD (=Chemical Vapor Deposition), sputtering and vacuum metallizing. Furthermore it is possible to use “dry” techniques, such as plasma etching, instead of wet chemical etching methods, and conversely.

Furthermore it is noted that the thin, selectively applied insulating layer 55 on the gate electrode 3D does not necessarily have to be removed after being formed. It may also be used as a permanent insulation on the upper side of the gate electrode 3D, so that a further conductive layer can be directly applied on top of said layer, if desired. Furthermore, the oxide layer 55 may be used for reversing the order in which the metal silicides of the source and drain regions 3A, 3B on the one hand and of the gate electrode 3D on the other hand are formed. Thus, the source and drain regions 3A, 3B may be provided with a metal silicide, if desired, after the formation of the gate electrode 3D as the first metal silicide.

It is furthermore noted that the device may comprise further active and passive semiconductor elements or electronic components, such as a larger number of diodes and/or transistors and resistors and/or capacitances, whether or not in the form of an integrated circuit. The manufacture will be efficiently geared thereto, of course. The invention is not only suitable for the manufacture of (C)MOS IC's, but also for the manufacture of discrete (P)MOS transistors.

1. A method of manufacturing a semiconductor device consisting of a substrate and a semiconductor body comprising a field effect transistor having a source and drain region and a channel region of a first conductivity type located therebetween and a gate electrode separated from the channel region by a dielectric layer, which gate electrode comprises a conductor, wherein a polycrystalline silicon layer is deposited on the semiconductor body provided with said dielectric layer so as to form the gate electrode, which polycrystalline silicon layer is subsequently removed again outside the channel region, and wherein a metal layer is deposited on the semiconductor body on top of the remaining portion of the polycrystalline silicon layer above the channel region, after which the remaining portion of the polycrystalline silicon layer is reacted with the metal layer by means of a thermal treatment, forming a metal suicide that forms the conductor for the gate electrode, after which the portion of the metal layer that remains after the reaction is removed by etching, characterized in that the semiconductor bodying is exposed in a thermal treatment to an atmosphere that comprises an oxygen-containing compound during or after the formation of the metal suicide.

2. A method as claimed in claim 1, characterized in that the metal suicide of the gate electrode is exposed during the formation thereof to an atmosphere comprising an oxygen-containing compound.

3. A method as claimed in claim 2, characterized in that the formation of the metal suicide and the exposure to the atmosphere comprising an oxygen-containing compound are carried out in a single thermal treatment step.

4. A method as claimed in claim 3, characterized in that platinum or palladium is selected as the material for the metal layer.

5. A method as claimed in claim 4, characterized in that a, preferably water-diluted, mixture of concentrated hydrochloric acid and concentrated nitric acid is used for etching the remaining portion of the metal layer.

6. A method as claimed in claim 5, characterized in that a (rapid) thermal tempering step is used as the thermal treatment, using a temperature in a range of about 400 degrees Celsius to about 700 degrees Celsius and a period in a range of about 30 seconds to about 20 minutes.

7. A method as claimed in claim 6, characterized in that the n-conductivity type is selected for the first conductivity type, as a result of which the transistor being formed is formed as a PMOS transistor.

8. A method as claimed in claim 7, characterized in that furthermore a second transistor is formed as an NMOS transistor in the semiconductor body.

9. A method as claimed in claim 8, characterized in that the NMOS transistor is provided with a gate electrode made up of a silicide of Hafnium or Yterbium.

10. A semiconductor device obtained by using a method as claimed in claim 9.
